(19) United States
(12) Patent Application Publication
(10) Pub. No.: US 2025/0241067 A1
(43) Pub. Date: Jul. 24, 2025

(54) METHOD FOR MANUFACTURING ACTIVE MATRIX SUBSTRATE, METHOD FOR MANUFACTURING LIQUID CRYSTAL DISPLAY DEVICE, ACTIVE MATRIX SUBSTRATE, AND LIQUID CRYSTAL DISPLAY DEVICE

(71) Applicant: Sharp Display Technology Corporation, Kameyama City (JP)

(72) Inventors: Hitoshi Takahata, Kameyama City (JP); Tohru Daitoh, Kameyama City (JP); Tetsuo Kikuchi, Kameyama City (JP); Setsuji Nishimiya, Kameyama City (JP); Masahiko Suzuki, Kameyama City (JP)

(21) Appl. No.: 19/027,540

(22) Filed: Jan. 17, 2025

(30) Foreign Application Priority Data
Jan. 24, 2024 (JP) 2024-008557

(51) Int. Cl. H10D 86/60; H10D 86/01; H10D 86/40

(52) U.S. Cl. CPC H10D 86/60; H10D 86/0212; H10D 86/423; H10D 86/451

(57) ABSTRACT

A method for manufacturing an active matrix substrate includes (A) forming a plurality of TFTs on a substrate, (B) forming an interlayer insulating layer covering the plurality of TFTs, (C) forming a plurality of touch wiring lines on the interlayer insulating layer, (D) forming a first dielectric layer covering the plurality of touch wiring lines, (E) forming a common electrode on the first dielectric layer, (F) forming a second dielectric layer covering the common electrode, and (G) forming a plurality of pixel electrodes on the second dielectric layer. The interlayer insulating layer includes an organic insulating layer, and the forming an interlayer insulating layer (B) includes (B1) forming the organic insulating layer including a plurality of openings and a plurality of bump portions protruding upward by using a multi-tone photomask.

### CROSS-REFERENCE TO RELATED APPLICATIONS

This application claims the benefit of priority to Japanese Patent Application Number 2024-008557 filed on Jan. 24, 2024. The entire contents of the above-identified application are hereby incorporated by reference.

### BACKGROUND

### Technical Field

The disclosure relates to a method for manufacturing an active matrix substrate and a method for manufacturing a liquid crystal display device. The disclosure also relates to an active matrix substrate and a liquid crystal display device.

In a liquid crystal display device including an active matrix substrate, a pixel electrode and a switching element are provided on a pixel-by-pixel basis. As a switching element, a thin film transistor (hereinafter, referred to as a “TFT”) is widely used. In each pixel, a TFT is electrically connected to the pixel electrode.

It has also been proposed to use an oxide semiconductor as a material of an active layer of the TFT in place of amorphous silicon or polycrystalline silicon. In the present specification, a portion of an active matrix substrate corresponding to a pixel of a liquid crystal display device is referred to as a “pixel region” or a “pixel”. Further, a TFT provided as a switching element in each pixel is referred to as a “pixel TFT”, and a connection portion that electrically connects the pixel TFT and a pixel electrode in each pixel is referred to as a “pixel contact portion”.

As a display mode of the liquid crystal display device, a transverse electrical field mode such as a Fringe Field Switching (FFS) mode may be employed. In the transverse electrical field mode, a pair of electrodes (a pixel electrode and a common electrode) are provided in the active matrix substrate to apply a transverse electrical field to a liquid crystal molecule.

An active matrix substrate used in a liquid crystal display device of the transverse electrical field mode may have a structure in which the common electrode is disposed above the pixel electrode (hereinafter, referred to as a “common upper layer structure”), or have a structure in which the common electrode is disposed below the pixel electrode (hereinafter, referred to as a “common lower layer structure”). An active matrix substrate having the common lower layer structure is described in, for example, JP 2013-109347 A.

On the other hand, in recent years, display devices provided with touch sensors (called “touch panels”) have been widely used in smartphones, tablets, and the like. Various types of touch sensors are known, such as a resistive film type, an electrostatic capacitive type, and an optical type.

Touch panels are roughly classified into a type in which a touch sensor is externally attached to a display device (“external type”) and a type in which a touch sensor is built in a display device (“built-in type”). The built-in touch panel is more advantageous for thickness and weight reduction, and the like than the external touch panel, and has an advantage of increasing a transmittance of light.

The built-in touch panel includes an on-cell touch panel and an in-cell touch panel. Here, a “cell” refers to a display panel. The “in-cell type” refers to those provided with a layer that serves as a touch sensor function in the display panel. The “on-cell type” refers to those provided with a layer that serves as a touch sensor function and is disposed between the display panel and the polarizer provided on the viewer side of the display panel.

In principle, the in-cell type can achieve the thinnest and lightest touch panel. An in-cell touch panel in which a touch sensor is built in a liquid crystal display device of the transverse electrical field mode is disclosed in, for example, WO 2016/136271.

### SUMMARY

In an in-cell touch panel, a display panel is frequently pressed by a finger or the like. Because of this, in the case where the display panel is a liquid crystal display panel, it is desired that a cell gap (thickness of the liquid crystal layer) is sufficiently secured even when the display panel is pressed.

An embodiment of the disclosure has been conceived in light of the above problems, and an object thereof is to provide an active matrix substrate suitably used in a liquid crystal display panel for an in-cell touch panel and a method for manufacturing the active matrix substrate.

The present specification discloses a method for manufacturing an active matrix substrate, a method for manufacturing a liquid crystal display device, an active matrix substrate, and a liquid crystal display device, which are described in the following items.

### Item 1

A method for manufacturing an active matrix substrate, the active matrix substrate including
a substrate,
a plurality of thin film transistors supported by the substrate, the plurality of thin film transistors each including an oxide semiconductor layer,
an interlayer insulating layer covering the plurality of thin film transistors,
a plurality of pixel electrodes disposed above the interlayer insulating layer,
a common electrode disposed between the plurality of pixel electrodes and the interlayer insulating layer, the common electrode including a plurality of segments configured to function as a plurality of touch sensor electrodes,
a first dielectric layer disposed between the interlayer insulating layer and the common electrode,
a second dielectric layer disposed between the common electrode and the plurality of pixel electrodes, and
a plurality of touch wiring lines disposed between the interlayer insulating layer and the common electrode, the plurality of touch wiring lines being each electrically connected to a corresponding touch sensor electrode of the plurality of touch sensor electrodes, the method including:
(A) forming the plurality of thin film transistors on the substrate;
(B) forming an interlayer insulating layer covering the plurality of thin film transistors;
(C) forming the plurality of touch wiring lines on the interlayer insulating layer;
(D) forming the first dielectric layer covering the plurality of touch wiring lines;
(E) forming the common electrode on the first dielectric layer;
(F) forming the second dielectric layer covering the common electrode; and
(G) forming the plurality of pixel electrodes on the second dielectric layer, wherein
the interlayer insulating layer includes an organic insulating layer, and
the forming an interlayer insulating layer (B) includes
(B1) forming the organic insulating layer including a plurality of openings and a plurality of bump portions protruding upward by using a multi-tone photomask.

### Item 2

The method for manufacturing an active matrix substrate according to Item 1, wherein
in the forming the organic insulating layer (B1), the organic insulating layer is formed of a photosensitive resin material.

### Item 3

The method for manufacturing an active matrix substrate according to Item 1 or 2, wherein
the forming the organic insulating layer (B1) is performed such that each of the plurality of bump portions at least partially overlaps each of the plurality of thin film transistors in a plan view.

### Item 4

The method for manufacturing an active matrix substrate according to any one of Items 1 to 3, wherein
each of the plurality of thin film transistors further includes a gate electrode, a source electrode, and a drain electrode,
the active matrix substrate further includes a plurality of pixel contact portions each electrically connecting one pixel electrode of the plurality of pixel electrodes to one thin film transistor of the plurality of thin film transistors corresponding to the one pixel electrode,
each of the plurality of pixel contact portions includes a connection electrode that electrically connects the one pixel electrode and the drain electrode of the one thin film transistor, and
the connection electrode is formed of a conductive film identical to the conductive film of the plurality of touch wiring lines in the forming the plurality of touch wiring lines (C).

### Item 5

The method for manufacturing an active matrix substrate according to any one of Items 1 to 4, wherein
each of the plurality of thin film transistors has a bottom gate structure.

### Item 6

The method for manufacturing an active matrix substrate according to any one of Items 1 to 5, wherein
the oxide semiconductor layer includes an In—Ga—Zn—O-based semiconductor.

### Item 7

A method for manufacturing a liquid crystal display device, the device including
an active matrix substrate,
a counter substrate disposed to oppose the active matrix substrate, and
a liquid crystal layer provided between the active matrix substrate and the counter substrate, the method including:
(a) preparing the active matrix substrate; and
(b) preparing the counter substrate, wherein
the preparing the active matrix substrate (a) is performed by the method for manufacturing an active matrix substrate according to any one of Items 1 to 6.

### Item 8

The method for manufacturing a liquid crystal display device according to Item 7, wherein
the counter substrate includes a plurality of columnar spacers that define a thickness of the liquid crystal layer, and
the plurality of bump portions of the organic insulating layer include two or more bump portions disposed to overlap the plurality of columnar spacers in a plan view.

### Item 9

An active matrix substrate, including:
a substrate;
a plurality of thin film transistors supported by the substrate, the plurality of thin film transistors each including an oxide semiconductor layer:
an interlayer insulating layer covering the plurality of thin film transistors;
a plurality of pixel electrodes disposed above the interlayer insulating layer;
a common electrode disposed between the plurality of pixel electrodes and the interlayer insulating layer, the common electrode including a plurality of segments configured to function as a plurality of touch sensor electrodes;
a first dielectric layer disposed between the interlayer insulating layer and the common electrode;
a second dielectric layer disposed between the common electrode and the plurality of pixel electrodes; and
a plurality of touch wiring lines disposed between the interlayer insulating layer and the common electrode, the plurality of touch wiring lines being each electrically connected to a corresponding touch sensor electrode of the plurality of touch sensor electrodes, wherein
the interlayer insulating layer includes an organic insulating layer, and
the organic insulating layer includes a plurality of openings and a plurality of bump portions protruding upward.

### Item 10

The active matrix substrate according to Item 9, wherein
each of the plurality of bump portions is disposed in such a manner as to at least partially overlap each of the plurality of thin film transistors in a plan view.

### Item 11

The active matrix substrate according to Item 9 or 10, further including:
a plurality of pixel contact portions each electrically connecting one pixel electrode of the plurality of pixel electrodes to one thin film transistor of the plurality of thin film transistors corresponding to the one pixel electrode, wherein
each of the plurality of thin film transistors further includes a gate electrode, a source electrode, and a drain electrode, and
each of the plurality of pixel contact portions includes a connection electrode that electrically connects the one pixel electrode and the drain electrode of the one thin film transistor, and that is formed of a conductive film identical to the conductive film of the plurality of touch wiring lines.

### Item 12

The active matrix substrate according to any one of Items 9 to 11, wherein
a protruding height of the plurality of bump portions of the organic insulating layer is 0.5 μm or more.

### Item 13

The active matrix substrate according to any one of Items 9 to 12, wherein
each of the plurality of thin film transistors has a bottom gate structure.

### Item 14

The active matrix substrate according to any one of items 9 to 13, wherein
the oxide semiconductor layer includes an In—Ga—Zn—O-based semiconductor.

### Item 15

A liquid crystal display device including:
the active matrix substrate according to any one of items 9 to 14;
a counter substrate disposed to oppose the active matrix substrate; and
a liquid crystal layer provided between the active matrix substrate and the counter substrate.

### Item 16

The liquid crystal display device according to Item 15, wherein
the counter substrate includes a plurality of columnar spacers that define a thickness of the liquid crystal layer, and
the plurality of bump portions of the organic insulating layer include two or more bump portions disposed to overlap the plurality of columnar spacers in a plan view.

According to the embodiment of the disclosure, there are provided an active matrix substrate suitably used in a liquid crystal display panel for an in-cell touch panel and a method for manufacturing the active matrix substrate.

### BRIEF DESCRIPTION OF DRAWINGS

The disclosure will be described with reference to the accompanying drawings, wherein like numbers reference like elements.

FIG. 1 is a diagram schematically illustrating a general structure of an active matrix substrate 101 according to an embodiment of the disclosure.

FIG. 2 is a plan view illustrating an arrangement relationship between touch sensor electrodes TX and touch wiring lines TL in the active matrix substrate 101 as an example.

FIG. 3 is a cross-sectional view schematically illustrating the active matrix substrate 101, where a cross section including a TFT 30, a pixel contact portion PC, and a touch wiring line contact portion TC is depicted.

FIG. 4 is a cross-sectional view schematically illustrating the active matrix substrate 101, where a columnar spacer SP is virtually depicted.

FIG. 5 is a cross-sectional view schematically illustrating an in-cell touch panel (liquid crystal display device) 1000 using the active matrix substrate 101.

FIG. 6A is a step cross-sectional view illustrating an example of a manufacturing method of the active matrix substrate 101.

FIG. 6B is a step cross-sectional view illustrating the example of the manufacturing method of the active matrix substrate 101.

FIG. 6C is a step cross-sectional view illustrating the example of the manufacturing method of the active matrix substrate 101.

FIG. 6D is a step cross-sectional view illustrating the example of the manufacturing method of the active matrix substrate 101.

FIG. 6E is a step cross-sectional view illustrating the example of the manufacturing method of the active matrix substrate 101.

FIG. 6F is a step cross-sectional view illustrating the example of the manufacturing method of the active matrix substrate 101.

FIG. 6G is a step cross-sectional view illustrating the example of the manufacturing method of the active matrix substrate 101.

FIG. 6H is a step cross-sectional view illustrating the example of the manufacturing method of the active matrix substrate 101.

FIG. 6I is a step cross-sectional view illustrating the example of the manufacturing method of the active matrix substrate 101.

FIG. 6J is a step cross-sectional view illustrating the example of the manufacturing method of the active matrix substrate 101.

FIG. 7 is a table showing the example of the manufacturing method of the active matrix substrate 101.

FIG. 8 is a cross-sectional view schematically illustrating an active matrix substrate 901 of a comparative example, where a cross section including a TFT 30, a pixel contact portion PC, and a touch wiring line contact portion TC is depicted.

FIG. 9 is a cross-sectional view schematically illustrating the active matrix substrate 901, where a columnar spacer SP is virtually depicted.

FIG. 10A is a step cross-sectional view illustrating a manufacturing method of the active matrix substrate 901.

FIG. 10B is a step cross-sectional view illustrating the manufacturing method of the active matrix substrate 901.

FIG. 10C is a step cross-sectional view illustrating the manufacturing method of the active matrix substrate 901.

FIG. 10D is a step cross-sectional view illustrating the manufacturing method of the active matrix substrate 901.

FIG. 10E is a step cross-sectional view illustrating the manufacturing method of the active matrix substrate 901.

FIG. 10F is a step cross-sectional view illustrating the manufacturing method of the active matrix substrate 901.

FIG. 10G is a step cross-sectional view illustrating the manufacturing method of the active matrix substrate 901.

FIG. 11 is a table showing the manufacturing method of the active matrix substrate 901.

### DESCRIPTION OF EMBODIMENTS

Hereinafter, an embodiment of the disclosure will be described with reference to the drawings, but the disclosure is not limited to the embodiment described below.

### General Structure of Active Matrix Substrate

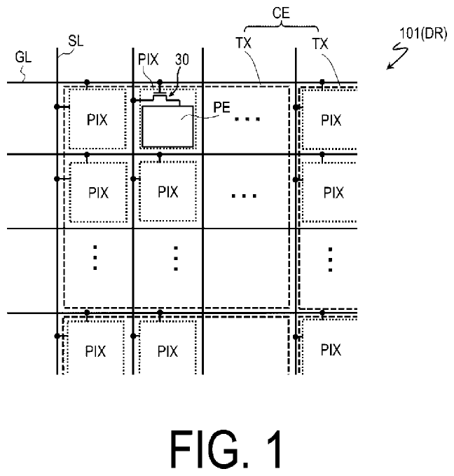

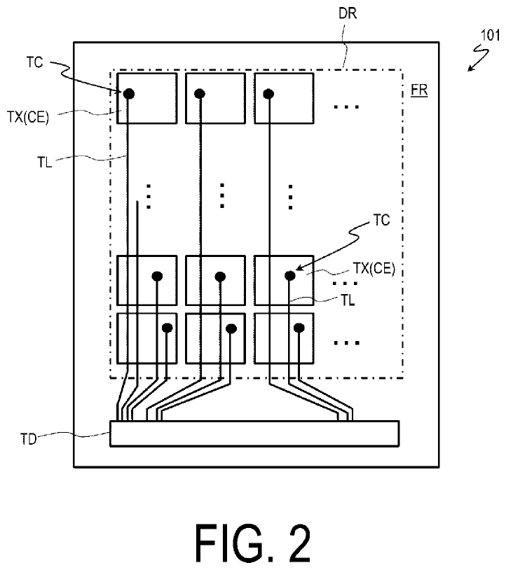

First, a general structure of an active matrix substrate 101 according to the embodiment of the disclosure will be described with reference to FIG. 1 and FIG. 2. The active matrix substrate 101 may be used in an in-cell touch panel using a liquid crystal display panel of the FFS mode. A touch sensor built in the touch panel may be of, for example, a mutual capacitance type or a self-capacitance type. FIG. 1 is a diagram schematically illustrating a general structure of the active matrix substrate 101. FIG. 2 is a plan view illustrating an arrangement relationship between touch sensor electrodes TX and touch wiring lines TL in the active matrix substrate 101 as an example.

The active matrix substrate 101 has a display region DR and a non-display region FR located around the display region DR, as illustrated in FIG. 2. The non-display region FR is referred to as a “peripheral region” or “frame region” in some cases.

In the display region DR, as illustrated in FIG. 1, there are included a plurality of gate bus lines (scanning wiring lines) GL extending in a row direction, a plurality of source bus lines (signal wiring lines) SL extending in a column direction, and a plurality of pixel regions PIX arrayed in a matrix shape. The column direction is a direction intersecting with the row direction and may be orthogonal to the row direction. The pixel region PIX is a region corresponding to each pixel in a liquid crystal display device. In the example illustrated in FIG. 1, each pixel region PIX is defined by two gate bus lines GL adjacent to each other and two source bus lines SL adjacent to each other.

Each pixel region PIX is provided with a TFT (pixel TFT) 30 and a pixel electrode PE. A gate electrode of the TFT 30 is electrically connected to the corresponding gate bus line GL, and a source electrode of the TFT 30 is electrically connected to the corresponding source bus line SL. A drain electrode of the TFT 30 is electrically connected to the corresponding pixel electrode PE in a pixel contact portion PC described below.

The active matrix substrate 101 is provided with a common electrode CE. The common electrode CE is divided into a plurality of segments TX. Each segment TX functions as a touch sensor electrode. In the example illustrated in FIG. 1, each touch sensor electrode TX is provided corresponding to two or more pixel regions PIX.

As illustrated in FIG. 2, the active matrix substrate 101 includes a plurality of the touch wiring lines TL. Each touch wiring line TL is electrically connected to the corresponding touch sensor electrode TX. Hereinafter, a connection portion TC between the touch wiring line TL and the touch sensor electrode TX is referred to as a “touch wiring line contact portion”.

The touch wiring line TL is connected to a touch drive unit TD provided in the non-display region FR. The touch drive unit TD is configured to switch, for example, between a display mode in which the plurality of touch sensor electrodes TX function as the common electrode CE, and a touch detection mode in which the plurality of touch sensor electrodes TX function as the touch sensor electrode TX, in a time division manner. The touch drive unit TD, for example, inputs a common signal to the touch sensor electrode TX (common electrode CE) through the touch wiring line TL in the display mode. On the other hand, in the touch detection mode, the touch drive unit TD inputs a touch drive signal to the touch sensor electrode TX through the touch wiring line TL.

In the example illustrated in FIG. 2, the plurality of touch wiring lines TL extend in the column direction (the direction in which the source bus lines SL extend). Some touch wiring lines TL extend to the corresponding touch sensor electrodes TX across one or more of the other touch sensor electrodes TX.

Although not illustrated, in the non-display region FR of the active matrix substrate 101, in addition to the touch drive unit TD, drive circuits such as a gate driver that supplies scanning signals to the TFT 30 via the gate bus line GL and a source driver that supplies display signals to the TFT 30 via the source bus line SL are provided. These drive circuits may be, for example, mounted on the active matrix substrate 101 or formed in an integrated (monolithic) form. A semiconductor chip including some or all of the drive circuits may be mounted on the non-display region FR.

In the above explanation, an example is described in which the touch panel includes a touch sensor of the self-capacitance type, but the touch panel may include a touch sensor of the mutual capacitance type instead. In this case, another electrode for the touch sensor may be provided on the counter substrate disposed to oppose the active matrix substrate 101 with the liquid crystal layer interposed therebetween. For example, the touch sensor electrode TX may extend in one direction (e.g., the row direction), the electrode for the touch sensor provided on the counter substrate may extend in another direction (for example, in the column direction), and a change in capacitance of an intersecting portion (touch detection unit) of these electrodes may be detected. Specific structures, driving methods, and the like of the mutual capacitance type and self-capacitance type touch sensors are described in, for example, JP 2018-5484 A, WO 2018/092758, WO 2017/126603, JP 2016-126336 A, and JP 2009-244958 A and are publicly known, so that detailed description thereof will be omitted. The entire contents of the disclosures of JP 2018-5484 A, WO 2018/092758, WO 2017/126603, JP 2016-126336 A, and JP 2009-244958 A are incorporated herein by reference.

Herein, regardless of the type of the touch sensor, the electrode for the touch sensor disposed on the active matrix substrate 101 side is simply referred to as the “touch sensor electrode TX”, and the wiring line for the touch sensor electrically connected to the touch sensor electrode TX is referred to as the “touch wiring line”.

### Structure of Pixel Region in Active Matrix Substrate

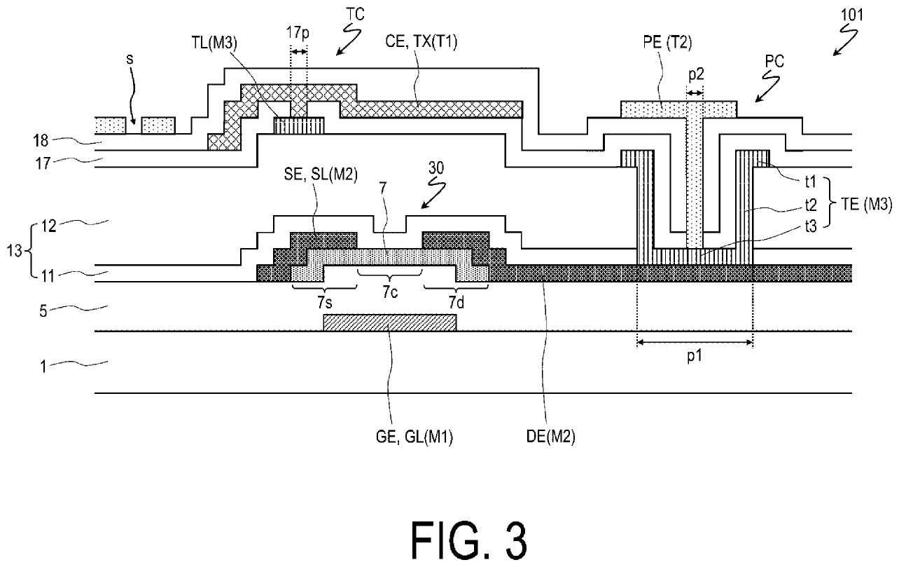

Next, the structure of the pixel region PIX in the active matrix substrate 101 will be described with reference to FIG. 3. FIG. 3 is a cross-sectional view schematically illustrating the active matrix substrate 101, where a cross section including the TFT 30, the pixel contact portion PC, and the touch wiring line contact portion TC is depicted.

In this specification, a layer M1 including electrodes and wiring lines formed using the same conductive film (first conductive film) as the gate bus line GL is referred to as a “first metal layer”, and a layer M2 including electrodes and wiring lines formed using the same conductive film (second conductive film) as the source bus line SL is referred to as a “second metal layer”. Further, a layer M3 including electrodes and wiring lines formed using the same conductive film as the touch wiring line TL (third conductive film) is referred to as a “third metal layer”. In addition, a layer T1 including electrodes and wiring lines formed using the same conductive film (first transparent conductive film) as the common electrode CE is referred to as a “first transparent conductive layer”, and a layer T2 including electrodes and wiring lines formed using the same conductive film (second transparent conductive film) as the pixel electrode PE is referred to as a “second transparent conductive layer”. In the drawings, a reference sign for each of constituent elements may be followed by a sign indicating the metal layer or the transparent conductive layer in parentheses. For example, “(M1)” may be added after the reference sign of the electrode or wiring line formed in the first metal layer M1.

As illustrated in FIG. 3, the active matrix substrate 101 includes a substrate 1, a plurality of the TFTs 30 supported by the substrate 1, an interlayer insulating layer 13 covering the plurality of TFTs 30, a plurality of the pixel electrodes PE arranged above the interlayer insulating layer 13, and the common electrodes CE arranged between the pixel electrodes PE and the interlayer insulating layer 13.

Each of the plurality of TFTs 30 is disposed corresponding to each of the plurality of pixel regions PIX. Part of the TFT 30 may be located outside the corresponding pixel region PIX.

Each TFT 30 is provided with a gate electrode GE, an oxide semiconductor layer 7, a gate insulating layer 5 arranged between the oxide semiconductor layer 7 and the gate electrode GE, and a source electrode SE and a drain electrode DE electrically connected to the oxide semiconductor layer 7.

In the illustrated example, the TFT 30 has a bottom gate structure, where the gate electrode GE is arranged between the oxide semiconductor layer 7 and the substrate 1. The gate electrode GE overlaps at least part of the oxide semiconductor layer 7 with the gate insulating layer 5 interposed therebetween. The gate insulating layer 5 covers the gate electrode GE.

The oxide semiconductor layer 7 is arranged on the gate insulating layer 5 so as to overlap the gate electrode GE with the gate insulating layer 5 interposed therebetween. The oxide semiconductor layer 7 has a source contact region 7s, a drain contact region 7d, and a channel region 7c.

The source contact region 7s is electrically connected to the source electrode SE, and the drain contact region 7d is electrically connected to the drain electrode DE. The source electrode SE may be in direct contact with the source contact region 7s, and the drain electrode DE may be in direct contact with the drain contact region 7d. The channel region 7c is a region that is located between the source contact region 7s and the drain contact region 7d, and overlaps the gate electrode GE.

The gate electrode GE is electrically connected to the corresponding gate bus line GL, and the source electrode SE is electrically connected to the corresponding source bus line SL. The drain electrode DE is electrically connected to the corresponding pixel electrode PE in the pixel contact portion PC.

The gate electrode GE may be formed in the same layer (first metal layer M1) as the gate bus line GL. The gate electrode GE may be part of the corresponding gate bus line GL. The source electrode SE and the drain electrode DE may be formed in the same layer (second metal layer M2) as the source bus line SL. The source electrode SE may be part of the corresponding source bus line SL.

The TFT 30 is covered with the interlayer insulating layer 13. The interlayer insulating layer 13 includes an organic insulating layer 12. The organic insulating layer 12 has a thickness (for example, 1 μm or more) sufficient to function as a flattening film. In the illustrated example, the interlayer insulating layer 13 has a layered structure including an inorganic insulating layer (passivation film) 11 and the organic insulating layer 12 arranged on the inorganic insulating layer 11.

The plurality of touch wiring lines TL are provided on the interlayer insulating layer 13. In the illustrated example, each touch wiring line TL is arranged to overlap one source bus line SL among the plurality of source bus lines SL with the interlayer insulating layer 13 interposed therebetween, and extends on the source bus line SL along the source bus line SL (that is, in the column direction) in a plan view.

A first dielectric layer 17 is arranged on the interlayer insulating layer 13 so as to cover the third metal layer M3 including the touch wiring line TL. The common electrode CE is provided on the first dielectric layer 17. Therefore, it can be said that the first dielectric layer 17 is disposed between the interlayer insulating layer 13 and the common electrode CE. Further, it can be said that the touch wiring line TL is also disposed between the interlayer insulating layer 13 and the common electrode CE.

The common electrode CE is divided into the plurality of segments capable of functioning as the plurality of touch sensor electrodes TX. Each touch sensor electrode TX typically corresponds to two or more pixel regions PIX (that is, has a size corresponding to two or more pixel regions PIX).

Each touch sensor electrode TX is electrically connected to the corresponding touch wiring line TL in an opening 17p formed in the first dielectric layer 17 in the touch wiring line contact portion TC. For one touch sensor electrode TX, it is sufficient that at least one touch wiring line contact portion TC is provided, or two or more touch wiring line contact portions TC may be provided.

The common electrode CE (touch sensor electrode TX) is covered with a second dielectric layer 18. There is provided the pixel electrode PE on the second dielectric layer 18. Therefore, it can be said that the second dielectric layer 18 is disposed between the common electrode CE and the pixel electrode PE.

At least one slit s is formed in the pixel electrode PE. The pixel electrode PE is arranged to partially overlap the common electrode CE with the second dielectric layer 18 interposed therebetween (a region where the two electrodes overlap each other is not illustrated in FIG. 3). The pixel electrode PE is electrically connected to the TFT 30 in the pixel contact portion PC.

### Pixel Contact Portion

The active matrix substrate 101 includes a plurality of the pixel contact portions PC, each of which electrically connects one pixel electrode PE of the plurality of pixel electrodes PE to one TFT 30 of the plurality of TFTs 30 corresponding to the one pixel electrode PE. In the illustrated example, the pixel electrode PE is electrically connected to the drain electrode DE of the TFT 30 with a connection electrode TE formed using the same third conductive film as the touch wiring line TL (that is, formed in the third metal layer M3) in each pixel contact portion PC.

As illustrated in FIG. 3, the pixel contact portion PC includes part of the drain electrode DE of the TFT 30, part of the pixel electrode PE, and the connection electrode TE. A lower opening p1 is formed in the interlayer insulating layer 13 to expose part of the drain electrode DE, and the connection electrode TE is electrically connected to the drain electrodes DE in the lower opening p1. In the illustrated example, the connection electrode TE is in direct contact with an exposed portion of the drain electrode DE in the lower opening p1.

An upper opening p2 is formed in the first dielectric layer 17 and the second dielectric layer 18 to expose part of the connection electrode TE, and the pixel electrode PE is electrically connected to the connection electrode TE in the upper opening p2. In the illustrated example, the pixel electrode PE is in direct contact with an exposed portion of the connection electrode TE in the upper opening p2.

In the illustrated example, the third metal layer M3 including the touch wiring line TL is arranged closer to the substrate 1 side than the common electrode CE. Thus, the third metal layer M3 can be used for forming the pixel contact portion PC. Specifically, when the pixel contact portion PC is formed, in a state where the drain electrode DE is covered with the connection electrode TE, the first transparent conductive film is patterned to form the common electrode CE. Thus, in the process of patterning the first transparent conductive film to form the common electrode CE, damage to the drain electrode DE due to contact of the etching solution (for example, oxalic acid) with the drain electrode DE can be suppressed.

In the illustrated example, the connection electrode TE includes a first portion t1 in contact with part of an upper face of the interlayer insulating layer 13, a second portion t2 in contact with a side surface of the lower opening p1, and a third portion t3 in contact with the exposed portion of the drain electrode DE. This makes it possible to more effectively protect the exposed portion of the drain electrode DE exposed by the lower opening p1. In particular, when the interlayer insulating layer 13 includes the organic insulating layer 12, it is preferable that the connection electrode TE not only cover the exposed portion of the drain electrode DE, but also cover a side surface of the organic insulating layer 12. As a result, it is possible to suppress the penetration of an etching solution into the drain electrode DE more effectively. In addition, corrosion of the drain electrode DE due to moisture contained in the organic insulating layer 12 can be suppressed. The side surface of the lower opening p1 includes the side surface of the inorganic insulating layer 11 and the side surface of the organic insulating layer 12. As illustrated in the figure, the second portion t2 of the connection electrode TE may cover the entire side surface of the lower opening p1. In this case, the first dielectric layer 17 does not need to be in contact with the side surface of the lower opening p1.

### Structure of Organic Insulating Layer

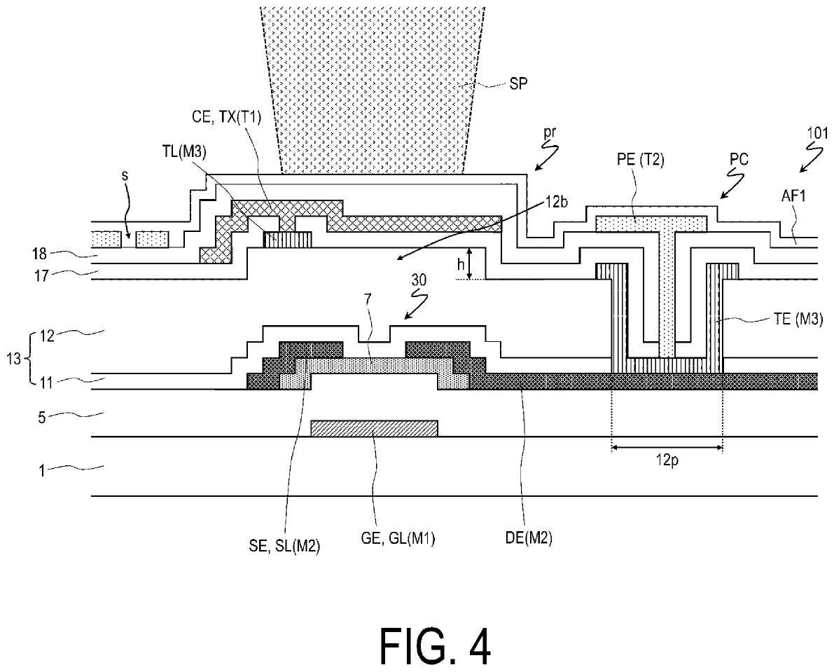

The structure of the organic insulating layer 12 will be described with reference to FIG. 4. Similar to FIG. 3, FIG. 4 is a cross-sectional view schematically illustrating the active matrix substrate 101. Further, FIG. 4 virtually depicts a columnar spacer SP, which is provided on the counter substrate side in the liquid crystal display device and defines the thickness of the liquid crystal layer. In addition, an alignment film (first alignment film) AF1 located on the outermost surface of the active matrix substrate 101 is also illustrated.

The organic insulating layer 12 has a plurality of openings 12p. Each of the plurality of openings 12p is located in the pixel contact portion PC of each pixel region PIX, and is part of the lower opening p1 of the interlayer insulating layer 13.

The organic insulating layer 12 further includes a plurality of bump portions (protruding portions) 12b protruding upward. The outermost surface of the active matrix substrate 101 has a protruding portion pr corresponding to the bump portion 12b (reflecting the protrusion of the bump portion 12b).

In the illustrated example, each of the plurality of bump portions 12b is disposed to at least partially overlap each of the plurality of TFTs 30 in a plan view. The plurality of bump portions 12b include two or more bump portions 12b disposed to overlap a plurality of the columnar spacers SP provided on the counter substrate side in the plan view. FIG. 4 illustrates the bump portion 12b overlapping the columnar spacer SP, but some of the bump portions 12b are not needed to overlap the columnar spacer SP.

The organic insulating layer 12 may be made of a photosensitive resin material, for example. Further, as will be described later, by using a multi-tone photomask in the step of forming the organic insulating layer 12, the organic insulating layer 12 having the bump portion 12b in addition to the opening 12p can be easily formed (in the same number of steps as in the case of forming an organic insulating layer having no bump portion).

As described above, in the active matrix substrate 101 according to the embodiment of the disclosure, since the organic insulating layer 12 includes the plurality of bump portions 12b, the protruding portions pr corresponding to the bump portions 12b are formed on the outermost surface of the active matrix substrate 101. Since the protruding portion pr can function as a structure (base) for receiving the columnar spacer SP, in the liquid crystal display panel using the active matrix substrate 101, the cell gap is sufficiently secured even when pressed by a finger or the like. Accordingly, the active matrix substrate 101 is suitably used in a liquid crystal display panel for an in-cell touch panel.

Although a protruding height h of the bump portion 12b is not particularly limited, the protruding height h of the bump portion 12b is preferably 0.5 μm or more from the viewpoint of sufficiently securing the cell gap when the liquid crystal display panel is pressed.

The shape of the bump portion 12b in a plan view is also not particularly limited, and may take various shapes such as a substantially circular shape, a substantially elliptical shape, a substantially rectangular shape, and a substantially regular polygonal shape. There is also no particular limitation on the size of the bump portion 12 in the plan view, but the equivalent circle diameter of the bump portion 12b in the plan view is, for example, 10 μm or more and 40 μm or less.

### Configuration of Touch Panel

The active matrix substrate 101 according to the embodiment of the disclosure is suitably used for an in-cell touch panel.

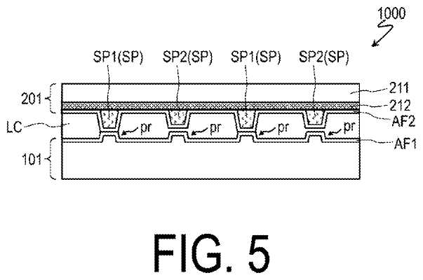

FIG. 5 is a cross-sectional view schematically illustrating a touch panel (liquid crystal display device) 1000 using the active matrix substrate 101. The touch panel 1000 includes the active matrix substrate 101, a counter substrate 201 disposed to oppose the active matrix substrate 101, and a liquid crystal layer LC provided between the active matrix substrate 101 and the counter substrate 201, as illustrated in FIG. 5.

The counter substrate 201 includes a substrate 211, a color filter layer 212 supported by the substrate 211, and the plurality of columnar spacers SP provided on the color filter layer 212. A second alignment film AF2 is provided on the outermost surface of the counter substrate 201 on the liquid crystal layer LC side.

The color filter layer 212 includes, for example, a red color filter, a green color filter, and a blue color filter. The color filter layer 212 typically further includes a black matrix (light blocking layer).

In the illustrated example, the plurality of columnar spacers SP include a first spacer SP1 and a second spacer SP2 lower than the first spacer SP1. The first spacer SP1 may be referred to as a “main spacer”, while the second spacer SP2 may be referred to as a “sub-spacer”.

As described above, the protruding portion pr located on the outermost surface of the active matrix substrate 101 functions as a structure (base) for receiving the columnar spacer SP, whereby the cell gap can be sufficiently secured even when the panel surface is pressed.

### Method for Manufacturing Active Matrix Substrate

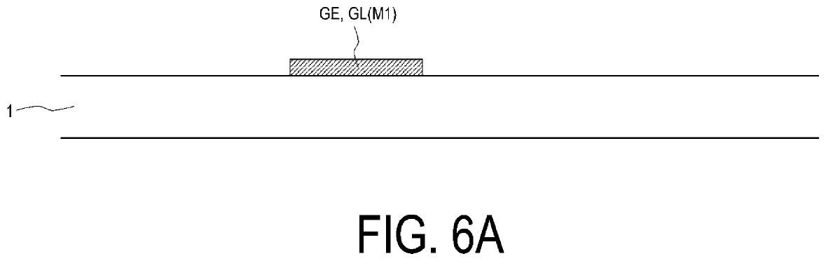

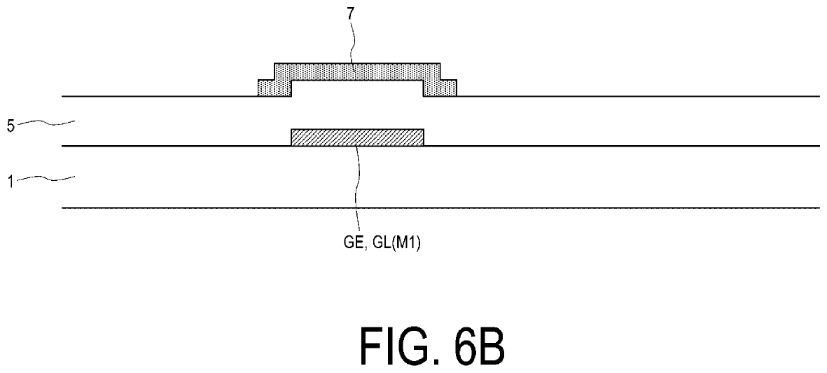

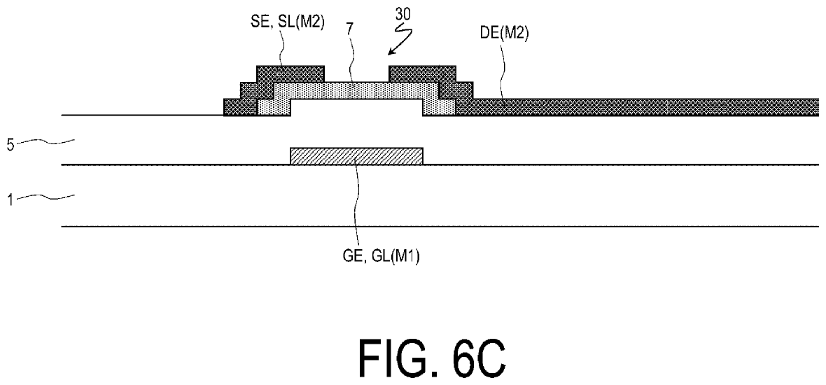

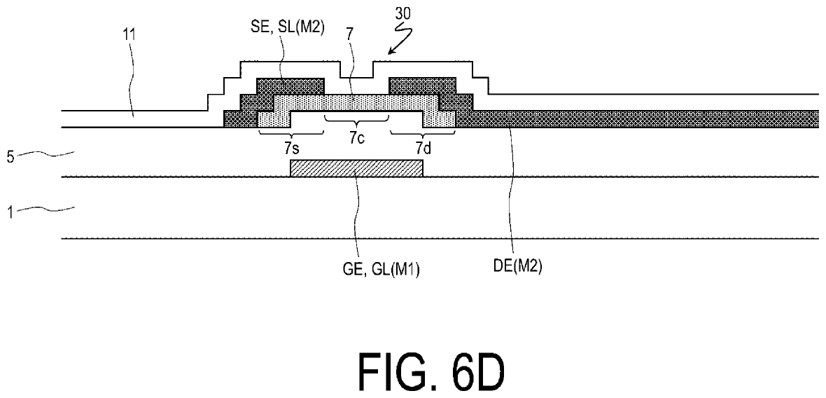

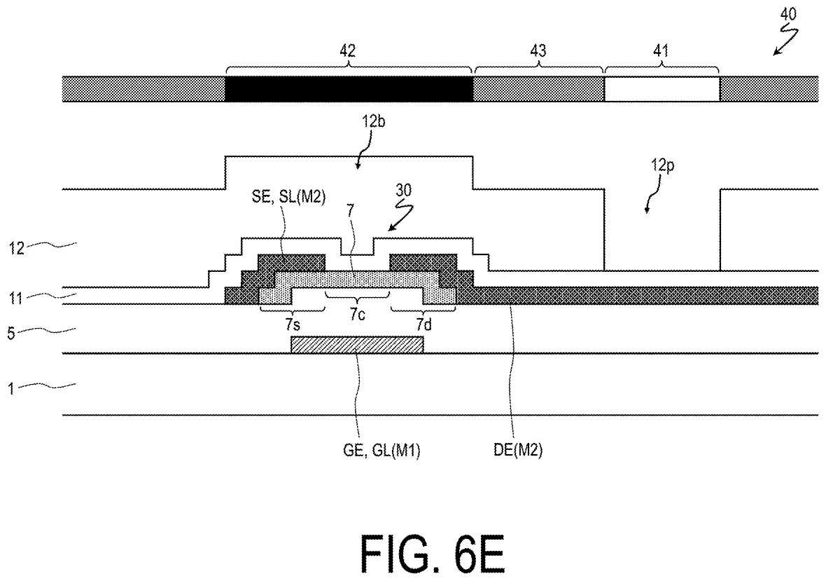

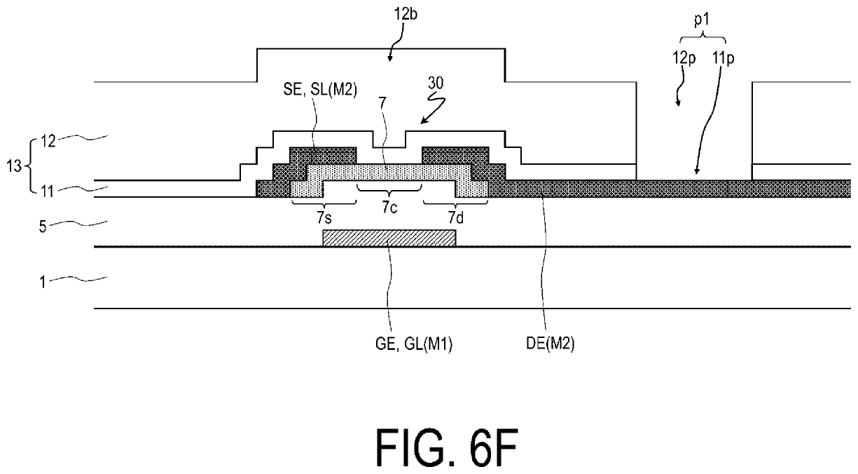

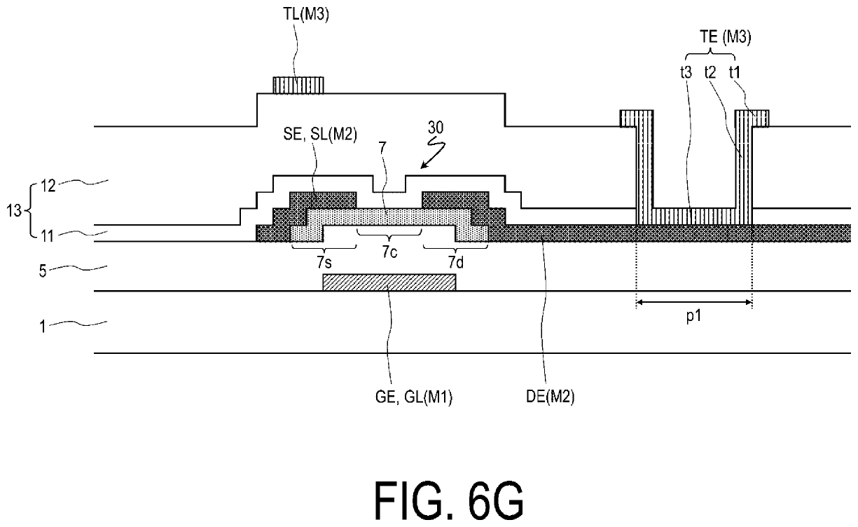

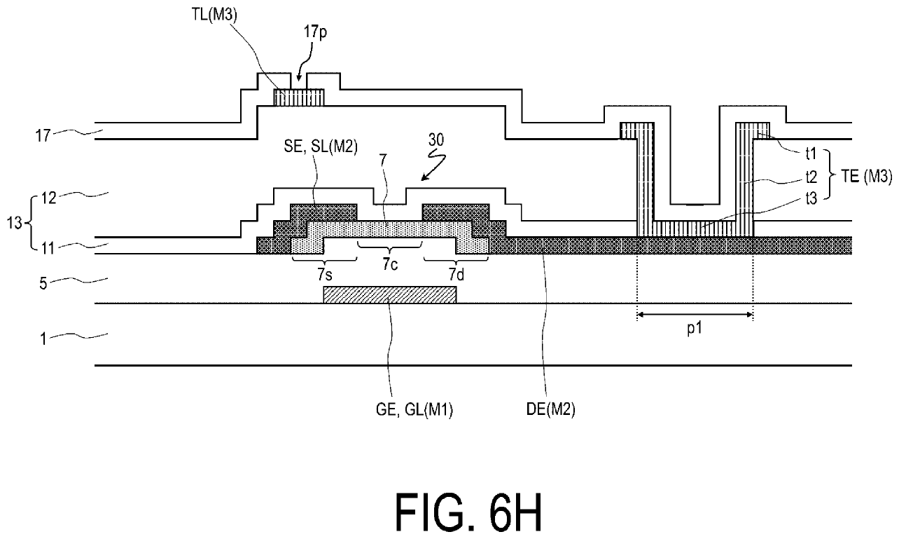

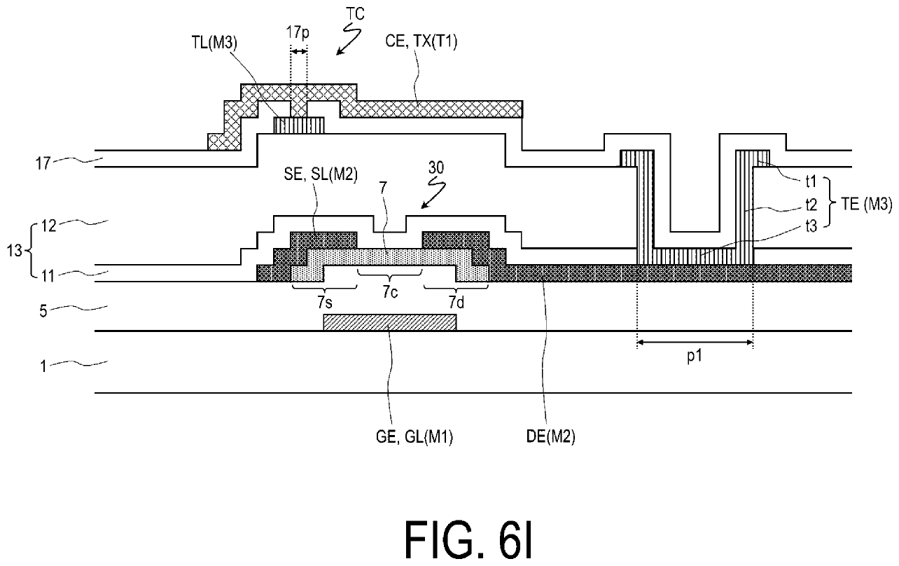

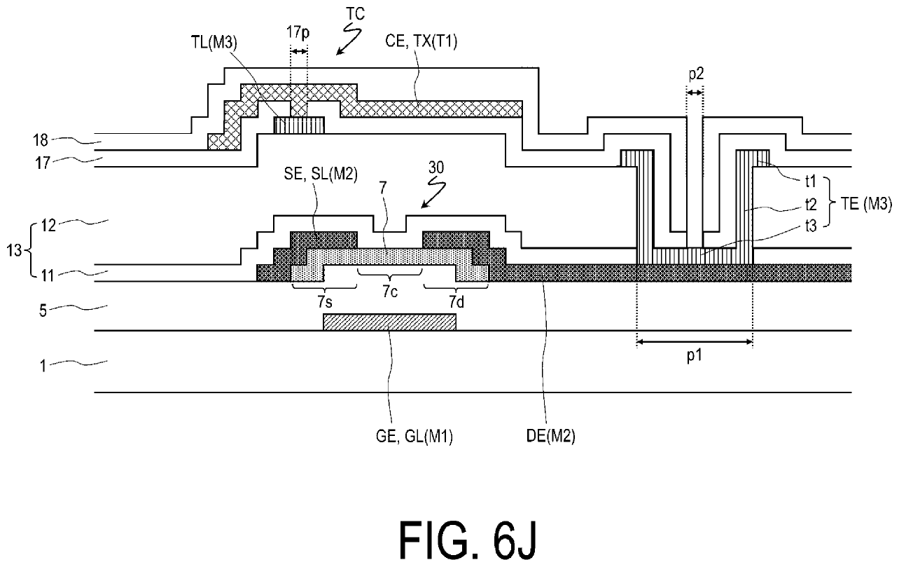

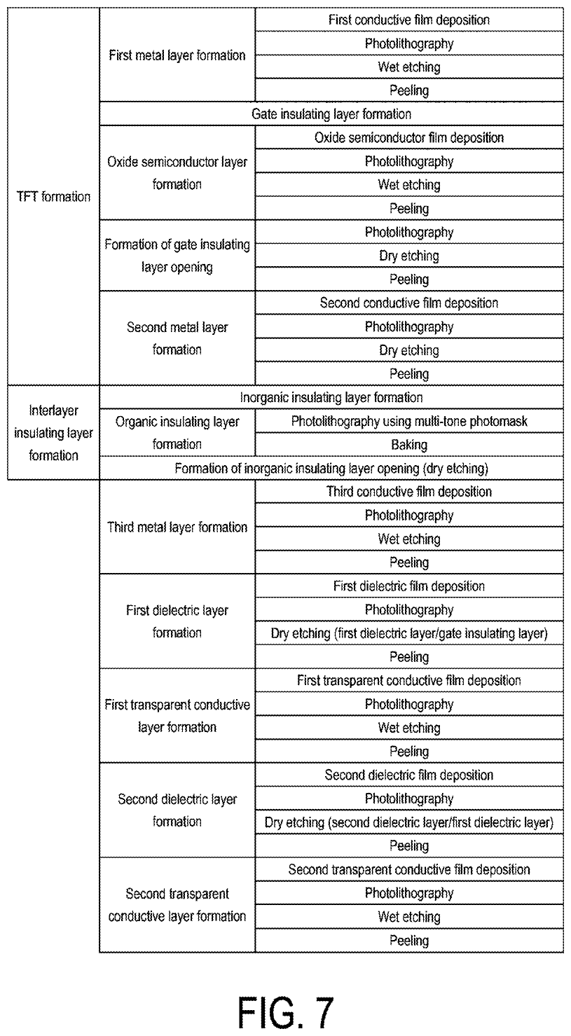

Next, a manufacturing method of the active matrix substrate 101 will be described with reference to FIG. 6A to FIG. 6J, and FIG. 7. FIGS. 6A to 6J illustrate step cross-sectional views of an example of the manufacturing method of the active matrix substrate 101. FIG. 7 is a table showing the example of the manufacturing method of the active matrix substrate 101.

### Formation of First Metal Layer M1 (FIG. 6A)

As illustrated in FIG. 6A, the first metal layer M1 is formed on the substrate 1. First, the first conductive film (thickness: for example, in a range from 50 nm to 500 nm) is deposited on the substrate 1 by, for example, a sputtering technique. Subsequently, a resist mask is formed by a known photolithography technique, and the first conductive film is patterned (for example, wet etching). Thereafter, the resist mask is peeled off. In this way, the first metal layer M1 including the gate bus line GL and the gate electrode GE is formed.

As the substrate 1, a transparent substrate with insulating properties, for example, a glass substrate, a silicon substrate, a heat-resistant plastic substrate (resin substrate), or the like can be used.

The material of the first conductive film is not particularly limited, and a metal such as aluminum (Al), tungsten (W), molybdenum (Mo), tantalum (Ta), chromium (Cr), titanium (Ti) or copper (Cu), an alloy containing these metals, or nitride of these metals can be appropriately used. The first conductive film may be a single layer or may have a layered structure.

### Formation of Gate Insulating Layer 5 and Oxide Semiconductor Layer 7 (FIG. 6B)

As illustrated in FIG. 6B, the gate insulating layer 5 (thickness: in a range from 200 nm to 600 nm, for example) is formed to cover the first metal layer M1, and then the oxide semiconductor layer 7 is formed on the gate insulating layer 5.

The gate insulating layer 5 is formed by CVD, for example. As a material of the gate insulating layer 5, silicon oxide (SiO₂), silicon nitride (SiNx), silicon oxynitride (SiOxNy; x>y), silicon nitride oxide (SiNxOy; x>y), or the like may be used as appropriate. The gate insulating layer 5 may be a single layer or may have a layered structure. For example, a silicon nitride layer or a silicon nitride oxide layer may be formed at the substrate 1 side (lower layer) in order to prevent diffusion of impurities or the like from the substrate 1, and a silicon oxide layer or a silicon oxynitride layer may be formed thereon (upper layer) in order to secure the insulating properties. Here, a layered film including a silicon nitride layer (thickness: in a range from 50 nm to 600 nm, for example) as a lower layer, and a silicon oxide layer (thickness: in a range from 50 nm to 600 nm, for example) as an upper layer is formed as the gate insulating layer 5. When an oxide layer such as a silicon oxide layer is used as the gate insulating layer 5 (as the top layer of the gate insulating layer 5 when the gate insulating layer 5 has a layered structure), the oxide layer can reduce the oxidation deficit generated in a channel region of the oxide semiconductor layer to be formed later, thereby making it possible to suppress a reduction in resistance of the channel region.

The oxide semiconductor layer 7 may be formed, for example, as follows. First, an oxide semiconductor film is deposited on the gate insulating layer 5 by a sputtering technique, for example. Thereafter, an annealing process of the oxide semiconductor film may be performed. The thickness of the oxide semiconductor film is in a range from 15 nm to 200 nm, for example. Here, as the oxide semiconductor film, an In—Ga—Zn—O-based semiconductor film (having a thickness of 50 nm) containing In, Ga, and Zn is deposited. Subsequently, by a known photolithography technique, a resist mask is formed, and the oxide semiconductor film is patterned (for example, wet etching). Thereafter, the resist mask is peeled off. In this manner, the oxide semiconductor layer 7 to be an active layer of the TFT 30 is formed in each pixel region PIX.

### Formation of Opening of Gate Insulating Layer 5

By using a known photolithography technique, a resist mask is formed, and the gate insulating layer 5 is patterned (for example, dry etching). Thereafter, the resist mask is peeled off. Thus, an opening is formed at a predetermined position of the gate insulating layer 5. The opening formed here is used, for example, for electrically connecting a wiring line formed in the first metal layer M1 and a wiring line formed in the second metal layer M2.

### Formation of Second Metal Layer M2 (FIG. 6C)

As illustrated in FIG. 6C, the second metal layer M2 is formed. First, the second conductive film (thickness: in a range from 50 nm to 500 nm, for example) is deposited on the oxide semiconductor layer 7 by using a sputtering technique, for example. Subsequently, by using a known photolithography technique, a resist mask is formed, and the second conductive film is patterned (for example, dry etching). Thereafter, the resist mask is peeled off. In this way, the second metal layer M2 including the source bus line SL, the source electrode SE, and the drain electrode DE is formed.

The material of the second conductive film is not particularly limited, and a metal such as aluminum (Al), tungsten (W), molybdenum (Mo), tantalum (Ta), chromium (Cr), titanium (Ti) or copper (Cu), an alloy containing these metals, or nitride of these metals can be appropriately used. The second conductive film may be a single layer or may have a layered structure.

By performing the step of forming the first metal layer M1 (FIG. 6A) to the step of forming the second metal layer M2 (FIG. 6C), the plurality of TFTs 30 can be formed on the substrate 1.

### Formation of Inorganic Insulating Layer 11 (FIG. 6D)

As illustrated FIG. 6D, the inorganic insulating layer 11 (thickness: in a range from 0.1 μm to 1 μm, for example) covering the TFT 30 is formed by CVD, for example. Examples of the material of the inorganic insulating layer 11 may appropriately include silicon oxide, silicon nitride, silicon oxynitride, silicon nitride oxide, aluminum oxide, tantalum oxide, and the like. The inorganic insulating layer 11 may be a single layer or may have a layered structure.

### Formation of Organic Insulating Layer 12 (FIG. 6E)

As illustrated in FIG. 6E, the organic insulating layer (thickness: in a range from 2 μm to 4 μm, for example) 12 having the plurality of openings 12p and the plurality of bump portions 12b is formed on the inorganic insulating layer 11. For example, first, a positive-type photosensitive resin material (e.g., an acrylic resin material) is supplied on the inorganic insulating layer 11, subsequently, photolithographic treatment (exposure and development) is performed using a multi-tone photomask, and then baking is performed, whereby the organic insulating layer 12 can be formed. In FIG. 6E, a halftone mask 40 is illustrated as an example of the multi-tone photomask. The halftone mask 40 includes a transmissive region 41, which transmits light, a light blocking region 42, which does not substantially transmit light, and a semi-transmissive region 43, which is constituted of a semi-transmissive film and transmits light at a lower transmittance than that of the transmissive region 41. The opening 12p is formed corresponding to the transmissive region 41, and the bump portion 12b is formed corresponding to the light blocking region 42. As described above, by using a multi-tone photomask such as the halftone mask 40, the organic insulating layer 12 having the plurality of openings 12p and the plurality of bump portions 12b, (that is, the organic insulating layer 12 having three different heights), can be easily formed.

Note that the multi-tone photomask is not limited to the halftone mask 40. A graytone mask may be used as the multi-tone photomask. The graytone mask includes a transmissive region that transmits light, a light blocking region that does not substantially transmit light, and a semi-transmissive region in which a slit having a resolution equal to or less than a resolution of the exposure machine is formed and that transmits light at a lower transmittance than that of the transmissive region. Even when the graytone mask is used, the organic insulating layer 12 having the plurality of openings 12p and the plurality of bump portions 12b may be formed.

### Formation of Opening 11p of Inorganic Insulating Layer 11 (FIG. 6F)

As illustrated in FIG. 6F, an opening 11p is formed in the inorganic insulating layer 11 by, for example, dry etching while using the organic insulating layer 12 as a mask. Since the opening 11p of the inorganic insulating layer 11 is formed to be continuous with the opening 12p of the organic insulating layer 12, the interlayer insulating layer 13 has the lower opening p1 including the opening 11p of the inorganic insulating layer 11 and the opening 12p of the organic insulating layer 12.

By performing the step of forming the inorganic insulating layer 11 (FIG. 6D) to the step of forming the opening 11p of the inorganic insulating layer 11 (FIG. 6F), the interlayer insulating layer 13 covering the plurality of TFTs 30 can be formed.

### Formation of Third Metal Layer M3 (FIG. 6G)

As illustrated in FIG. 6G, the third metal layer M3 is formed. First, the third conductive film (thickness: in a range from 50 nm to 500 nm, for example) is deposited on the interlayer insulating layer 13 and in the lower opening p1 by, for example, a sputtering technique. Subsequently, a resist mask is formed by a known photolithography technique, and the third conductive film is patterned (for example, wet etching). Thereafter, the resist mask is peeled off. In this way, the third metal layer M3 including the plurality of touch wiring lines TL and a plurality of the connection electrodes TE is formed.

As a material of the third conductive film, those exemplified as the materials of the first conductive film and the second conductive film can be used. The third conductive film may be a single layer or may have a layered structure. The third conductive film may be, for example, a layered film including a transparent conductive film (thickness: in a range from 10 nm to 50 nm, for example) and a metal film (thickness: in a range from 100 nm to 400 nm, for example) disposed on the transparent conductive film. As a material of the transparent conductive film, the same material as that of the first transparent conductive film or second transparent conductive film to be described later can be used, for example. As a material of the metal film, those exemplified as the materials of the first conductive film and the second conductive film can be used.

### Formation of First Dielectric Layer 17 (FIG. 6H)

As illustrated in FIG. 6H, the first dielectric layer 17 covering the third metal layer M3 is formed. First, a first dielectric film (thickness: in a range from 100 nm to 500 nm, for example) is deposited to cover the third metal layer M3 by CVD, for example. Subsequently, by using a known photolithography technique, a resist mask is formed, and the first dielectric film is patterned (for example, dry etching). Thereafter, the resist mask is peeled off. As described above, the first dielectric layer 17 covering the third metal layer M3 is formed. The first dielectric layer 17 has the opening 17p, which exposes part of the touch wiring line TL. When the first dielectric film is patterned, the gate insulating layer 5 may also be patterned to form an opening for exposing part of the gate bus line GL.

Examples of the material of the first dielectric film may appropriately include silicon oxide, silicon nitride, silicon oxynitride, silicon nitride oxide, and the like. The first dielectric film may be a single layer or may have a layered structure.

### Formation of First Transparent Conductive Layer T1 (FIG. 6I)

As illustrated in FIG. 6I, the first transparent conductive layer T1 including the common electrode CE is formed on the first dielectric layer 17. First, the first transparent conductive film (thickness: in a range from 20 nm to 300 nm, for example) is deposited on the first dielectric layer 17 and in the opening 17p by, for example, a sputtering technique. Subsequently, a resist mask is formed by a known photolithography technique, and the first transparent conductive film is patterned (for example, wet etching). Thereafter, the resist mask is peeled off. Thus, the first transparent conductive layer T1 including the common electrode CE is formed.

As a material of the first transparent conductive film, metal oxide such as indium-tin oxide (ITO), indium-zinc oxide, or ZnO can be used.

### Formation of Second Dielectric Layer 18 (FIG. 6J)

As illustrated in FIG. 6J, the second dielectric layer 18 covering the first transparent conductive layer T1 including the common electrode CE is formed. First, a second dielectric film (thickness: in a range from 80 nm to 250 nm, for example) is deposited to cover the first transparent conductive layer T1 by CVD, for example. Subsequently, by using a known photolithography technique, a resist mask is formed, and the second dielectric film is patterned (for example, dry etching). Thereafter, the resist mask is peeled off. Thus, the second dielectric layer 18 covering the first transparent conductive layer T1 is formed. When the second dielectric film is patterned, the first dielectric layer 17 is also patterned to form the upper opening p2 for exposing part of the connection electrode TE.

Examples of the material of the second dielectric film may appropriately include silicon oxide, silicon nitride, silicon oxynitride, silicon nitride oxide, and the like. The second dielectric film may be a single layer or may have a layered structure.

### Formation of Second Transparent Conductive Layer T2 (FIG. 3)

The second transparent conductive layer T2 including the plurality of pixel electrodes PE is formed on the second dielectric layer 18. First, the second transparent conductive film (thickness: in a range from 20 nm to 300 nm, for example) is deposited on the second dielectric layer 18 and in the upper opening p2 by, for example, a sputtering technique. Subsequently, a resist mask is formed by a known photolithography technique, and the second transparent conductive film is patterned (for example, wet etching). Thereafter, the resist mask is peeled off. Thus, the second transparent conductive layer T2 including the plurality of pixel electrodes PE is formed.

As a material of the second transparent conductive film, metal oxide such as indium-tin oxide (ITO), indium-zinc oxide, or ZnO can be used.

In this manner, the active matrix substrate 101 illustrated in FIG. 3 is obtained.

### Active Matrix Substrate of Comparative Example

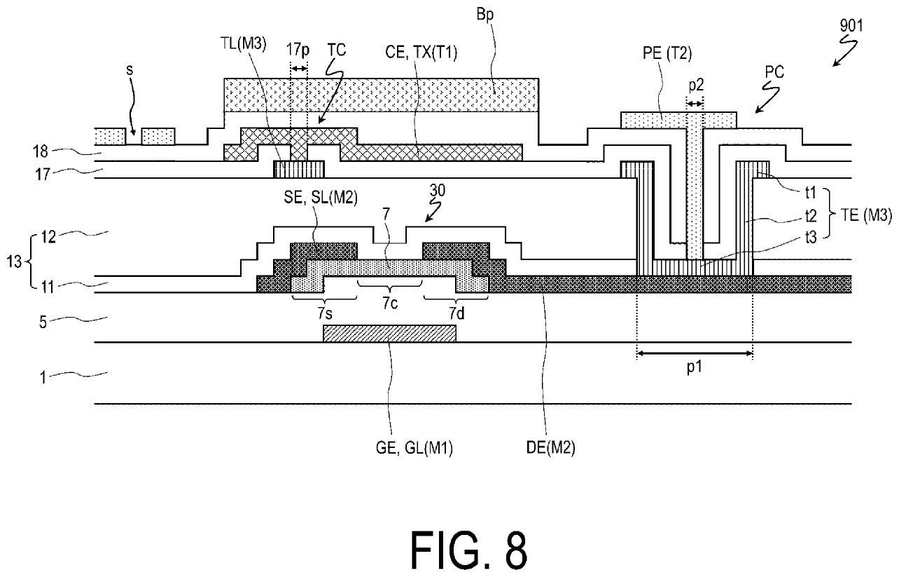

An active matrix substrate 901 of a comparative example will be described with reference to FIG. 8. FIG. 8 is a cross-sectional view schematically illustrating the active matrix substrate 901 of the comparative example.

The active matrix substrate 901 of the comparative example is different from the active matrix substrate 101 according to the embodiment of the disclosure in that an organic insulating layer 12 of an interlayer insulating layer 13 includes no bump portion. Further, the active matrix substrate 901 of the comparative example is different from the active matrix substrate 101 according to the embodiment of the disclosure in that there are provided a plurality of bumps Bp formed on a second dielectric layer 18. The bump Bp is formed of, for example, a negative-type resist material.

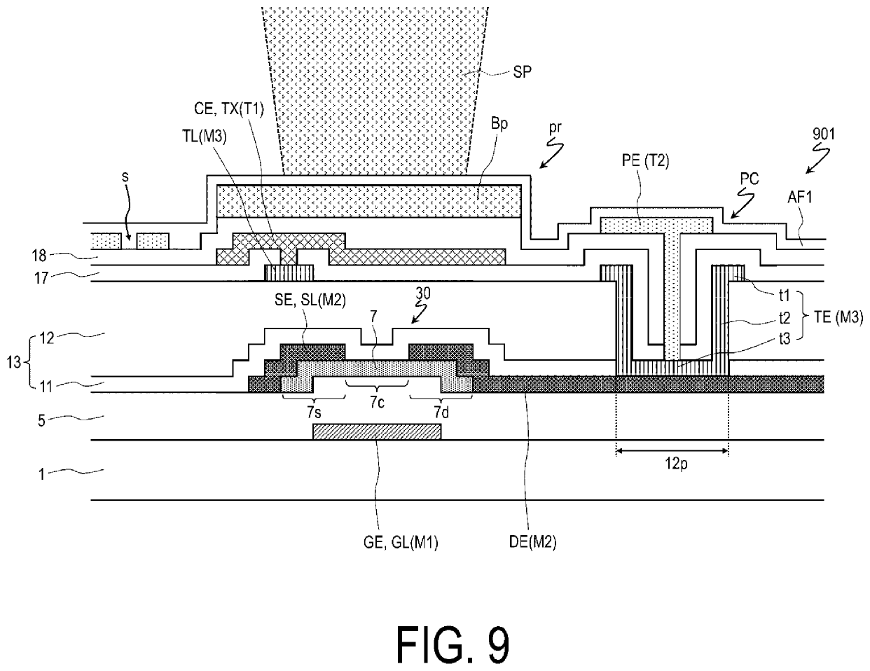

FIG. 9, similar to FIG. 8, is a cross-sectional view schematically illustrating the active matrix substrate 901 of the comparative example, where a columnar spacer SP is virtually depicted. In addition, an alignment film AF1 located on the outermost surface of the active matrix substrate 901 of the comparative example is also depicted.

The outermost surface of the active matrix substrate 901 of the comparative example has a protruding portion pr corresponding to the bump Bp. Since the protruding portion pr can function as a structure (base) for receiving the columnar spacer SP, in a liquid crystal display panel using the active matrix substrate 901 of the comparative example, the cell gap is sufficiently secured even when pressed by a finger or the like.

### Method for Manufacturing Active Matrix Substrate of Comparative Example

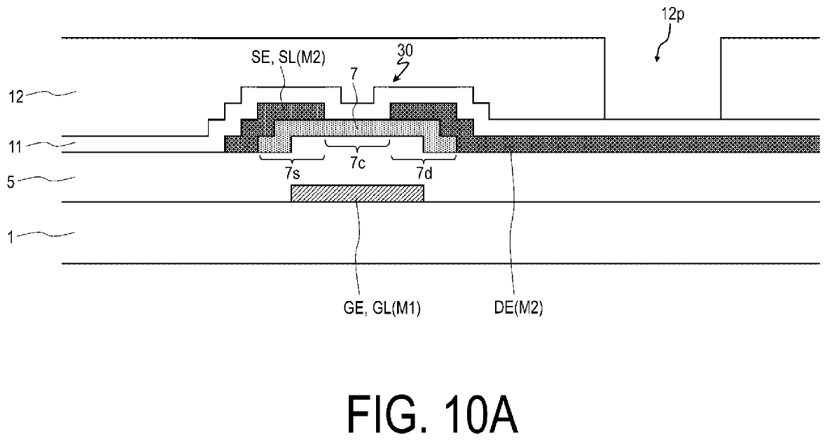

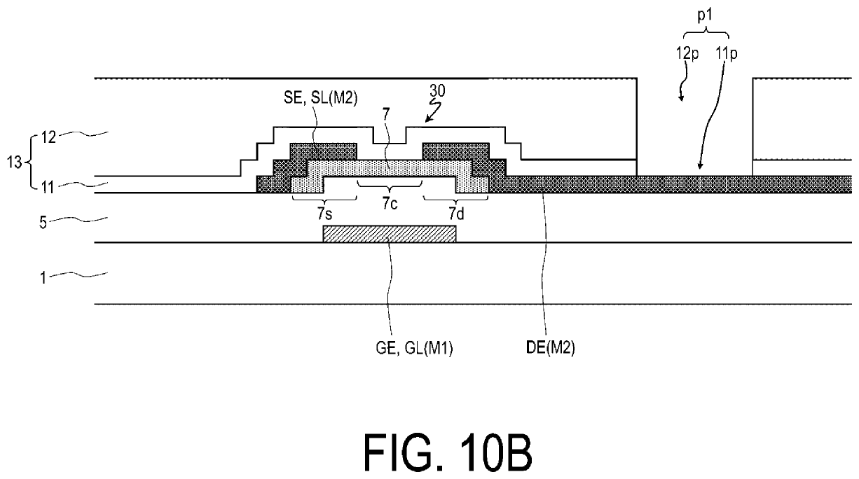

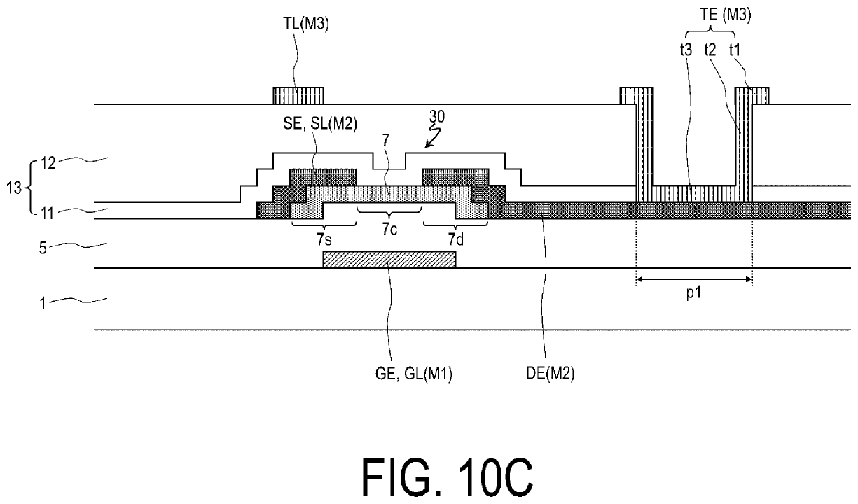

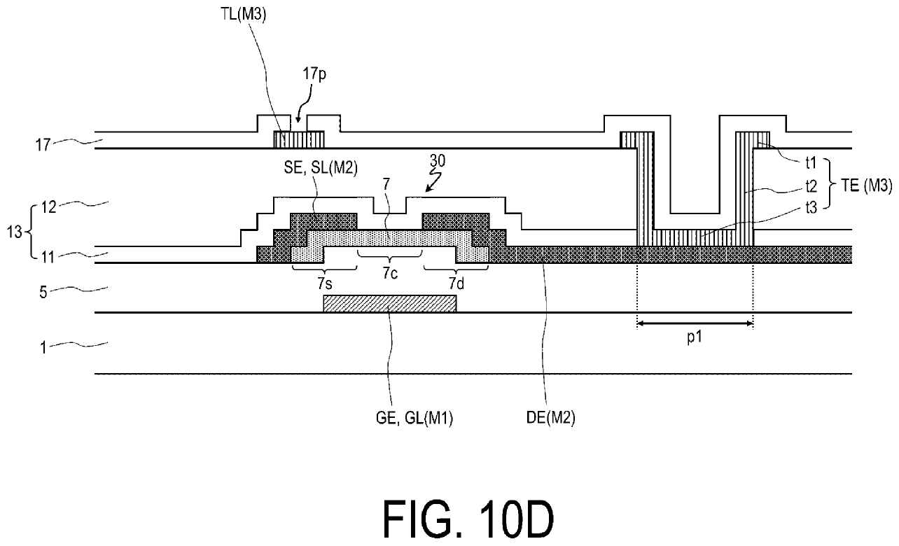

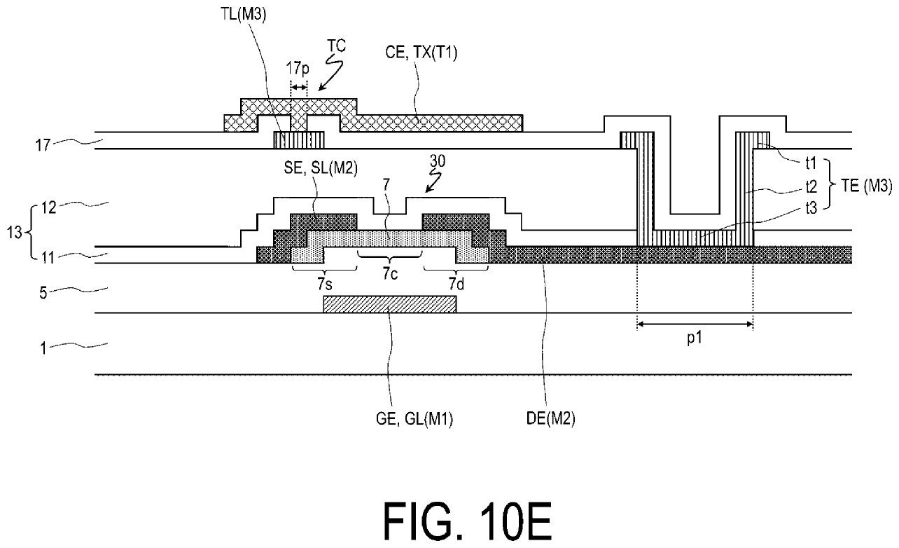

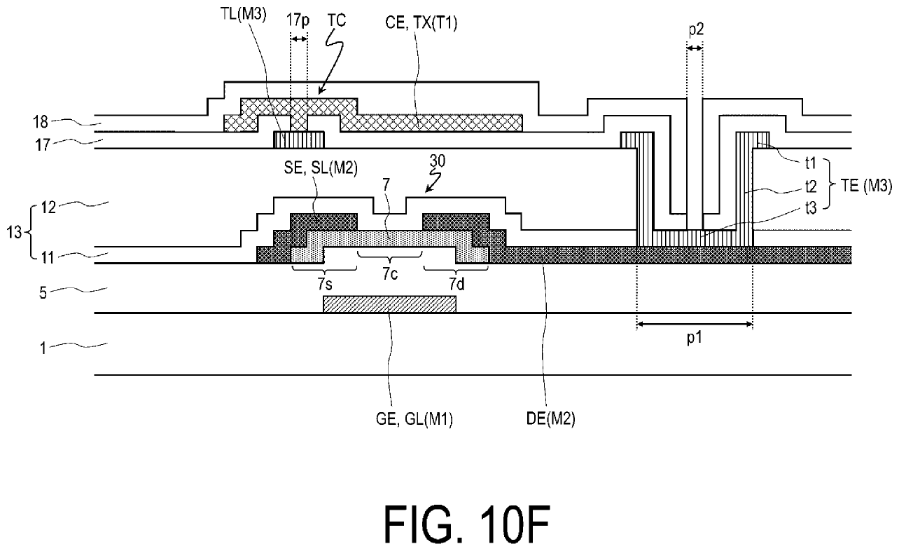

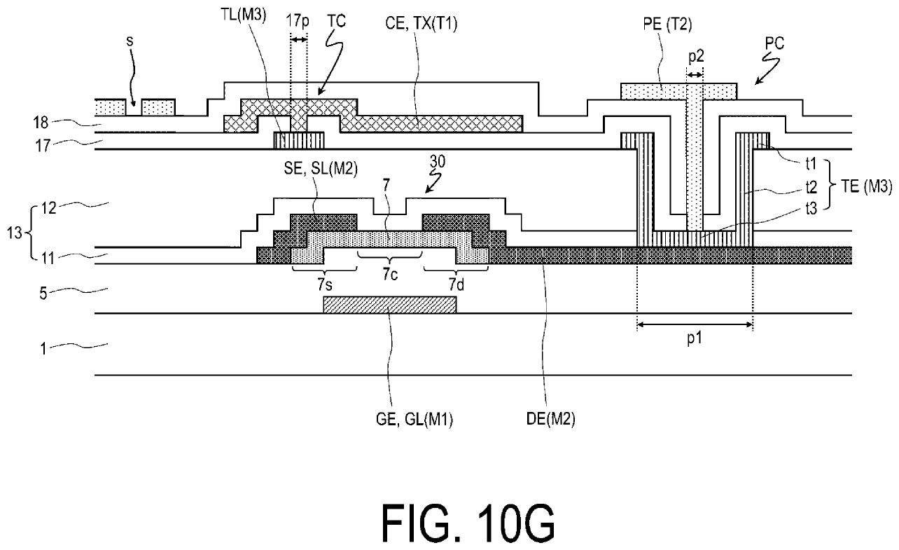

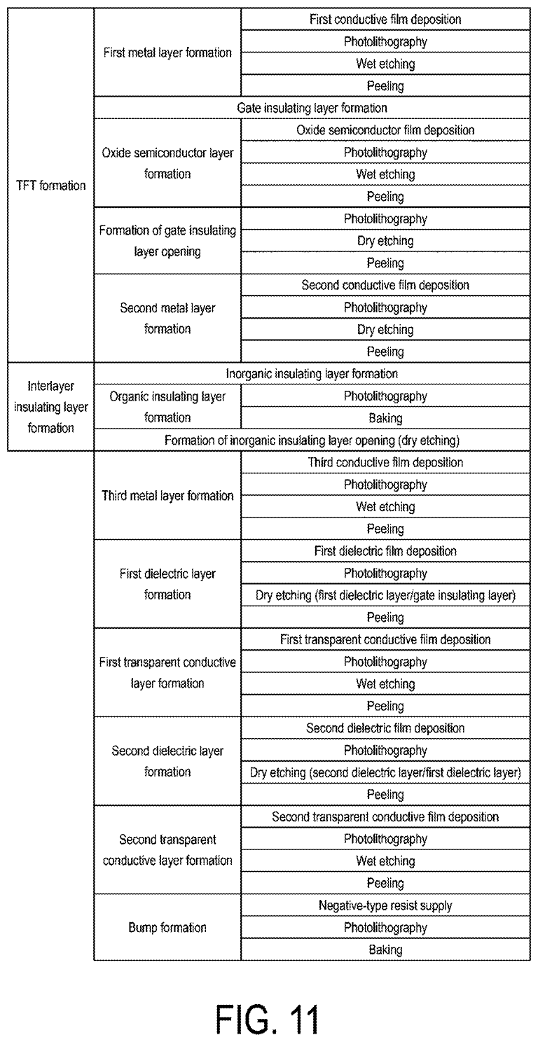

A manufacturing method of the active matrix substrate 901 of the comparative example will be described with reference to FIG. 10A to FIG. 10G, and FIG. 11. FIGS. 10A to 10G are step cross-sectional views illustrating the manufacturing method of the active matrix substrate 901 of the comparative example. FIG. 11 is a table showing the manufacturing method of the active matrix substrate 901 of the comparative example.

### Formation of First Metal Layer M1 to Formation of Inorganic Insulating Layer 11

A first metal layer M1, a gate insulating layer 5, an oxide semiconductor layer 7, a second metal layer M2, and an inorganic insulating layer 11 are sequentially formed in the same manner as described for the active matrix substrate 101 with reference to FIGS. 6A to 6D.

### Formation of Organic Insulating Layer 12 (FIG. 10A)

As illustrated in FIG. 10A, the organic insulating layer 12 having a plurality of openings 12p is formed on the inorganic insulating layer 11. For example, first, a positive-type photosensitive resin material is supplied on the inorganic insulating layer 11, subsequently, photolithographic treatment (exposure and development) is performed, and then baking is performed, whereby the organic insulating layer 12 can be formed.

### Formation of Opening 11p of Inorganic Insulating Layer 11 (FIG. 10B)

As illustrated in FIG. 10B, an opening 11p is formed in the inorganic insulating layer 11 by, for example, dry etching while using the organic insulating layer 12 as a mask. Since the opening 11p of the inorganic insulating layer 11 is formed to be continuous with the opening 12p of the organic insulating layer 12, the interlayer insulating layer 13 has a lower opening p1 including the opening 11p of the inorganic insulating layer 11 and the opening 12p of the organic insulating layer 12.

### Formation of Third Metal Layer M3 (FIG. 10C)

As illustrated in FIG. 10C, a third metal layer M3 is formed. First, a third conductive film is deposited on the interlayer insulating layer 13 and in the lower opening p1 by, for example, a sputtering technique. Subsequently, a resist mask is formed by a known photolithography technique, and the third conductive film is patterned (for example, wet etching). Thereafter, the resist mask is peeled off. In this way, the third metal layer M3 including a plurality of touch wiring lines TL and a plurality of connection electrodes TE is formed.

### Formation of First Dielectric Layer 17 (FIG. 10D)

As illustrated in FIG. 10D, a first dielectric layer 17 covering the third metal layer M3 is formed. First, a first dielectric film is deposited to cover the third metal layer M3 by CVD, for example. Subsequently, by using a known photolithography technique, a resist mask is formed, and the first dielectric film is patterned (for example, dry etching). Thereafter, the resist mask is peeled off. As described above, the first dielectric layer 17 covering the third metal layer M3 is formed. The first dielectric layer 17 has an opening 17p, which exposes part of the touch wiring line TL.

### Formation of First Transparent Conductive Layer T1 (FIG. 10E)

As illustrated in FIG. 10E, a first transparent conductive layer T1 including a common electrode CE is formed on the first dielectric layer 17. First, a first transparent conductive film is deposited on the first dielectric layer 17 and in the opening 17p by, for example, a sputtering technique. Subsequently, a resist mask is formed by a known photolithography technique, and the first transparent conductive film is patterned (for example, wet etching). Thereafter, the resist mask is peeled off. Thus, the first transparent conductive layer T1 including the common electrode CE is formed.

### Formation of Second Dielectric Layer 18 (FIG. 10F)

As illustrated in FIG. 10F, a second dielectric layer 18 covering the first transparent conductive layer T1 including the common electrode CE is formed. First, a second dielectric film is deposited to cover the first transparent conductive layer T1 by CVD, for example. Subsequently, by using a known photolithography technique, a resist mask is formed, and the second dielectric film is patterned (for example, dry etching). Thereafter, the resist mask is peeled off. Thus, the second dielectric layer 18 covering the first transparent conductive layer T1 is formed. When the second dielectric film is patterned, the first dielectric layer 17 is also patterned to form an upper opening p2 for exposing part of the connection electrode TE.

### Formation of Second Transparent Conductive Layer T2 (FIG. 10G)

A second transparent conductive layer T2 including a plurality of pixel electrodes PE is formed on the second dielectric layer 18. First, a second transparent conductive film is deposited on the second dielectric layer 18 and in the upper opening p2 by, for example, a sputtering technique. Subsequently, a resist mask is formed by a known photolithography technique, and the second transparent conductive film is patterned (for example, wet etching). Thereafter, the resist mask is peeled off. Thus, the second transparent conductive layer T2 including the plurality of pixel electrodes PE is formed.

### Formation of Bumps Bp (FIG. 8)

The plurality of bumps Bp are formed on the second dielectric layer 18. For example, first, a negative-type resist material is supplied on the second dielectric layer 18, subsequently, photolithographic treatment (exposure and development) is performed, and then baking is performed, whereby the Bumps Bp can be formed.

In this manner, the active matrix substrate 901 of the comparative example illustrated in FIG. 8 is obtained.

As discussed above, also in the liquid crystal display panel using the active matrix substrate 901 of the comparative example, the cell gap can be sufficiently secured even when pressed by a finger or the like. Note that, however, as can be understood from the comparison between FIG. 7 and FIG. 11, the number of steps can be reduced by adopting the configuration in which the organic insulating layer 12 of the interlayer insulating layer 13 has the plurality of bump portions 12b as in the active matrix substrate 101 according to the embodiment of the disclosure.

### Oxide Semiconductor

An oxide semiconductor (also referred to as a metal oxide, or an oxide material) included in the oxide semiconductor layer of a TFT may be an amorphous oxide semiconductor or a crystalline oxide semiconductor including a crystalline portion. Examples of the crystalline oxide semiconductor include a polycrystalline oxide semiconductor, a microcrystalline oxide semiconductor, and a crystalline oxide semiconductor having a c-axis oriented substantially perpendicular to the layer surface.

The oxide semiconductor layer may have a layered structure including two or more layers. When the oxide semiconductor layer has the layered structure, the oxide semiconductor layer may include an amorphous oxide semiconductor layer and a crystalline oxide semiconductor layer. Alternatively, the oxide semiconductor layer may include a plurality of crystalline oxide semiconductor layers having different crystal structures. The oxide semiconductor layer may include a plurality of amorphous oxide semiconductor layers. When the oxide semiconductor layer has a dual-layer structure that includes an upper layer and a lower layer, an energy gap of the oxide semiconductor included in a layer positioned at the gate electrode side of the two layers (that is, the lower layer in a case of a bottom gate structure, and the upper layer in a case of a top gate structure) may be smaller than an energy gap of the oxide semiconductor included in a layer positioned opposite to the gate electrode (that is, the upper layer in the case of the bottom gate structure, and the lower layer in the case of the top gate structure). Note that, in a case where a difference in the energy gap between these layers is relatively small, the energy gap of the oxide semiconductor included in the layer positioned on the gate electrode side may be greater than the energy gap of the oxide semiconductor included in the layer positioned opposite to the gate electrode.

Materials, structures, and film formation methods of an amorphous oxide semiconductor and the above-described crystalline oxide semiconductors, a configuration of an oxide semiconductor layer having a layered structure, and the like are described in, for example, JP 2014-007399 A. The entire contents of the disclosure of JP 2014-007399 A are incorporated in the present specification by reference.

The oxide semiconductor layer may include, for example, at least one metal element selected from In, Ga, and Zn. In the present embodiment, the oxide semiconductor layer includes, for example, an In—Ga—Zn—O-based semiconductor (for example, an indium gallium zinc oxide). Here, the In—Ga—Zn—O-based semiconductor is a ternary oxide of In (indium), Ga (gallium), and Zn (zinc), there is no particular limitation on a ratio (composition ratio) of In, Ga, and Zn, and examples of the ratio include In:Ga:Zn=2:2:1, In:Ga:Zn=1:1: 1, In:Ga:Zn=1:1:2, and the like. Such an oxide semiconductor layer can be formed of an oxide semiconductor film including an In—Ga—Zn—O-based semiconductor.

The In—Ga—Zn—O-based semiconductor may be an amorphous semiconductor or may be a crystalline semiconductor. A crystalline In—Ga—Zn—O-based semiconductor in which a c-axis is oriented substantially perpendicular to a layer surface is preferable as the crystalline In—Ga—Zn—O-based semiconductor.

Note that a crystal structure of the crystalline In—Ga—Zn—O-based semiconductor is disclosed, for example, in JP 2014-007399 A described above, JP 2012-134475 A, JP 2014-209727 A, and the like. The entire contents of the disclosures of JP 2012-134475 A and JP 2014-209727 A are incorporated in the present specification by reference. A TFT including an In—Ga—Zn—O-based semiconductor layer has a high mobility (more than 20 times as compared to an a-Si TFT) and a low leakage current (less than 1/100 as compared to the a-Si TFT). Thus, such a TFT can be suitably used as a drive TFT (for example, a TFT included in a drive circuit provided in a periphery of a display region including a plurality of pixels, and on the same substrate as the display region) and a pixel TFT (TFT provided in a pixel).

In place of the In—Ga—Zn—O-based semiconductor, the oxide semiconductor layer may include another oxide semiconductor. There may be included, for example, an In—Sn—Zn—O-based semiconductor (for example, In₂O₃—SnO₂—ZnO; InSnZnO). The In—Sn—Zn—O-based semiconductor is a ternary oxide of In (indium), Sn (tin), and Zn (zinc). Alternatively, the oxide semiconductor layer may include an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, cadmium oxide (CdO), a Mg—Zn—O-based semiconductor, an In—Ga—Sn—O-based semiconductor, an In—Ga—O-based semiconductor, a Zr—In—Zn—O-based semiconductor, a Hf—In—Zn—O-based semiconductor, an Al—Ga—Zn—O-based semiconductor, a Ga—Zn—O-based semiconductor, an In—Ga—Zn—Sn—O-based semiconductor, an In—W—Zn—O-based semiconductor, and the like.

### INDUSTRIAL APPLICABILITY

According to the embodiment of the disclosure, there are provided an active matrix substrate suitably used in a liquid crystal display panel for an in-cell touch panel and a method for manufacturing the active matrix substrate.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

1. A method for manufacturing an active matrix substrate, the active matrix substrate including
a substrate,
a plurality of thin film transistors supported by the substrate, the plurality of thin film transistors each including an oxide semiconductor layer,
an interlayer insulating layer covering the plurality of thin film transistors,
a plurality of pixel electrodes disposed above the interlayer insulating layer,
a common electrode disposed between the plurality of pixel electrodes and the interlayer insulating layer, the common electrode including a plurality of segments configured to function as a plurality of touch sensor electrodes,
a first dielectric layer disposed between the interlayer insulating layer and the common electrode,
a second dielectric layer disposed between the common electrode and the plurality of pixel electrodes, and
a plurality of touch wiring lines disposed between the interlayer insulating layer and the common electrode, the plurality of touch wiring lines being each electrically connected to a corresponding touch sensor electrode of the plurality of touch sensor electrodes, the method comprising:
(A) forming the plurality of thin film transistors on the substrate;
(B) forming an interlayer insulating layer covering the plurality of thin film transistors;
(C) forming the plurality of touch wiring lines on the interlayer insulating layer;
(D) forming the first dielectric layer covering the plurality of touch wiring lines;
(E) forming the common electrode on the first dielectric layer;
(F) forming the second dielectric layer covering the common electrode; and
(G) forming the plurality of pixel electrodes on the second dielectric layer,
wherein the interlayer insulating layer includes an organic insulating layer, and
the forming an interlayer insulating layer (B) includes
(B1) forming the organic insulating layer including a plurality of openings and a plurality of bump portions protruding upward by using a multi-tone photomask.

2. The method for manufacturing an active matrix substrate according to claim 1,
wherein in the forming the organic insulating layer (B1), the organic insulating layer is formed of a photosensitive resin material.

3. The method for manufacturing an active matrix substrate according to claim 1,
wherein the forming the organic insulating layer (B1) is performed such that each of the plurality of bump portions at least partially overlaps each of the plurality of thin film transistors in a plan view.

4. The method for manufacturing an active matrix substrate according to claim 1,
wherein each of the plurality of thin film transistors further includes a gate electrode, a source electrode, and a drain electrode,
the active matrix substrate further includes a plurality of pixel contact portions each electrically connecting one pixel electrode of the plurality of pixel electrodes to one thin film transistor of the plurality of thin film transistors corresponding to the one pixel electrode,
each of the plurality of pixel contact portions includes a connection electrode that electrically connects the one pixel electrode and the drain electrode of the one thin film transistor, and
the connection electrode is formed of a conductive film identical to the conductive film of the plurality of touch wiring lines in the forming the plurality of touch wiring lines (C).

5. The method for manufacturing an active matrix substrate according to claim 1,
wherein each of the plurality of thin film transistors has a bottom gate structure.

6. The method for manufacturing an active matrix substrate according to claim 1,
wherein the oxide semiconductor layer includes an In—Ga—Zn—O-based semiconductor.

7. A method for manufacturing a liquid crystal display device, the device including
an active matrix substrate,
a counter substrate disposed to oppose the active matrix substrate, and
a liquid crystal layer provided between the active matrix substrate and the counter substrate, the method comprising:
(a) preparing the active matrix substrate; and
(b) preparing the counter substrate,
wherein the preparing the active matrix substrate (a) is performed by the method for manufacturing an active matrix substrate according to claim 1.

8. The method for manufacturing a liquid crystal display device according to claim 7,
wherein the counter substrate includes a plurality of columnar spacers that define a thickness of the liquid crystal layer, and
the plurality of bump portions of the organic insulating layer include two or more bump portions disposed to overlap the plurality of columnar spacers in a plan view.

9. An active matrix substrate, comprising:
a substrate;
a plurality of thin film transistors supported by the substrate, the plurality of thin film transistors each including an oxide semiconductor layer;
an interlayer insulating layer covering the plurality of thin film transistors;
a plurality of pixel electrodes disposed above the interlayer insulating layer;
a common electrode disposed between the plurality of pixel electrodes and the interlayer insulating layer, the common electrode including a plurality of segments configured to function as a plurality of touch sensor electrodes;
a first dielectric layer disposed between the interlayer insulating layer and the common electrode;
a second dielectric layer disposed between the common electrode and the plurality of pixel electrodes; and
a plurality of touch wiring lines disposed between the interlayer insulating layer and the common electrode, the plurality of touch wiring lines being each electrically connected to a corresponding touch sensor electrode of the plurality of touch sensor electrodes,
wherein the interlayer insulating layer includes an organic insulating layer, and
the organic insulating layer includes a plurality of openings and a plurality of bump portions protruding upward.

10. The active matrix substrate according to claim 9,
wherein each of the plurality of bump portions is disposed in such a manner as to at least partially overlap each of the plurality of thin film transistors in a plan view.

11. The active matrix substrate according to claim 9, further comprising:
a plurality of pixel contact portions each electrically connecting one pixel electrode of the plurality of pixel electrodes to one thin film transistor of the plurality of thin film transistors corresponding to the one pixel electrode,
wherein each of the plurality of thin film transistors further includes a gate electrode, a source electrode, and a drain electrode, and
each of the plurality of pixel contact portions includes a connection electrode that electrically connects the one pixel electrode and the drain electrode of the one thin film transistor, and that is formed of a conductive film identical to the conductive film of the plurality of touch wiring lines.

12. The active matrix substrate according to claim 9,
wherein a protruding height of the plurality of bump portions of the organic insulating layer is 0.5 μm or more.

13. The active matrix substrate according to claim 9,
wherein each of the plurality of thin film transistors has a bottom gate structure.

14. The active matrix substrate according to claim 9,
wherein the oxide semiconductor layer includes an In—Ga—Zn—O-based semiconductor.

15. A liquid crystal display device, comprising:
the active matrix substrate according to claim 9;
a counter substrate disposed to oppose the active matrix substrate; and
a liquid crystal layer provided between the active matrix substrate and the counter substrate.

16. The liquid crystal display device according to claim 15,
wherein the counter substrate includes a plurality of columnar spacers that define a thickness of the liquid crystal layer, and
the plurality of bump portions of the organic insulating layer include two or more bump portions disposed to overlap the plurality of columnar spacers in a plan view.
